(19) United States
(12) Patent Application Publication
(10) Pub. No.: US 2025/0246550 A1
(43) Pub. Date: Jul. 31, 2025

(54) SEMICONDUCTOR DEVICE AND METHOD FOR FORMING THE SAME

(71) Applicant: Powerchip Semiconductor Manufacturing Corporation, Hsinchu (TW)

(72) Inventors: Meng-Han Lin, Hsinchu City (TW); Jih-Chien Chang, Taoyuan City (TW); Cheng-Ming Yih, Hsinchu City (TW); Chuen-Jiunn Shyu, Hsinchu City (TW); Jun-Cheng Lai, Hsinchu City (TW); Shou-Zen Chang, Hsinchu City (TW)

(73) Assignee: Powerchip Semiconductor Manufacturing Corporation, Hsinchu (TW)

(21) Appl. No.: 18/600,793

(22) Filed: Mar. 11, 2024

(30) Foreign Application Priority Data
Jan. 30, 2024 (TW) 113103535

(51) Int. Cl. H01L 23/532; H01L 21/762; H01L 21/768; H01L 29/423

(52) U.S. Cl. CPC H01L 23/5329; H01L 21/7621; H01L 21/76229; H01L 21/76832; H10D 64/514

(57) ABSTRACT

The present disclosure provides a semiconductor device and a method of forming the same. The semiconductor device includes a substrate including an element isolation structure defining first to third active regions and first to third elements respectively in the first to third active region. The first element includes a first gate dielectric layer embedded in the first active region of the substrate and isolation structures embedded in the substrate at opposite sides of the first gate dielectric layer. Bottom surfaces of the isolation structures include first portions at the same level as a bottom surface of the element isolation structure and second portions being oblique with respective to the first portions.

### CROSS-REFERENCE TO RELATED APPLICATION

This application claims the priority benefit of Taiwan application serial no. 113103535, filed on Jan. 30, 2024. The entirety of the above-mentioned patent application is hereby incorporated by reference herein and made a part of this specification.

### BACKGROUND

### Technical Field

The present invention relates to a semiconductor device and a method for forming the same.

### Description of Related Art

Power semiconductor components such as a power metal oxide semiconductor field effect transistor (MOSFET) are commonly used in analog circuits and/or digital circuits, and it can be divided into planar power semiconductor components and vertical power semiconductor components according to the direction of the current flow. In the planar power semiconductor component, the horizontal area of the semiconductor component and the thickness of the gate dielectric layer included in the semiconductor component are usually proportional to the operating voltage of the semiconductor component. For example, a high-voltage semiconductor component usually has a greater horizontal area and a thicker gate dielectric layer to endure a higher operating voltage.

In the current semiconductor manufacturing process, replacing the traditional polycrystalline silicon gate with a high-k metal gate (HKMG) is one of techniques to improve the performance of the semiconductor component. In the process of forming the HKMG, a gate-last technique is usually adopted to form a metal gate of the MOSFET. As the name suggests, in the gate-last technique, the metal gate of a gate structure is formed at last during the process of forming the gate structure of the MOSFET. For example, in the gate-last technique, a dummy gate is usually formed in advance to reserve a space where the metal gate is to be formed in the subsequent process. After forming an insulation layer (ILDO) surrounding the gate structure, the dummy gate is removed and then a metal material is filled into the space to replace the dummy gate with the metal gate.

When the process of the HKMG is applied to the high-voltage semiconductor component, the metal gate may encounter an over-polished issue since the high-voltage semiconductor component is designed to have a larger horizontal area, and therefore the gate height of the high-voltage semiconductor component becomes very important. In order to solve the over-polished issue, a recess may be formed in a region of a substrate defined by shallow trench isolation (STI) structures and where the gate dielectric layer is to be formed after the STI structures are formed, so that the metal gate subsequently formed above the recess is not prone to have the over-polished issue. However, the above process requires an additional mask and the gate dielectric layer may also have a thinning phenomenon at the edges adjacent to the STI structures, which affects the stability and performance (such as breakdown voltage) of the high-voltage semiconductor component.

Therefore, the skilled persons are still devoted to apply the process of the HKMG to the high-voltage semiconductor component without affecting the stability and performance of the high-voltage semiconductor component.

### SUMMARY

The invention provides a semiconductor device and a method for forming the same in which a first gate dielectric material layer is firstly formed in a substrate and then first trenches and a second trench where isolation structures and an element isolation structure are respectively formed therein are formed, so that the bottom surfaces of the isolation structures include first portions at the same level as a bottom surface of the element isolation structure and second portions being oblique with respective to the first portions As such, the thinning phenomenon does not occur at the edges of the gate dielectric layer adjacent to the isolation structures, and therefore the reliability and performance of the semiconductor device are good since the breakdown voltage of the semiconductor device is not affected by the above thinning phenomenon.

In addition, since there is no need to form a recess in a region of the substrate defined by the isolation structures and where the gate dielectric layer is to be formed, the active region of the semiconductor device will not be affected by the etching process used to form the recess. As such, the reliability of the semiconductor device can be improved and the problem related to the etching loading effect can be avoided as well, which allows the semiconductor device to have good yield and good performance.

An embodiment of the present invention provides a method for forming a semiconductor device, which includes: providing a substrate including a first active region, a second active region and a third active region; forming a first gate dielectric material layer embedded in the first active region of the substrate; removing portions of the first gate dielectric material layer and portions of the substrate next to the portions of the first gate dielectric material layer to form a first gate dielectric layer of a first element and first trenches at opposite sides of the first gate dielectric layer; forming a second trench defining the first active region, the second active region and the third active region in the substrate; and filling the first trenches and the second trench with an insulating material to form isolation structures in the first trenches and to form an element isolation structure in the second trench.

In some embodiments, the method for forming the semiconductor device further includes: forming a second gate dielectric layer of a second element and a third gate dielectric layer of a third element respectively on the second active region and the third active region of the substrate after forming the isolation structures and the element isolation structure.

In some embodiments, a horizontal area of the first element is greater than a horizontal area of the second element and a horizontal area of the third element.

In some embodiments, a top surface of the first gate dielectric layer is coplanar with top surfaces of the isolation structures.

In some embodiments, the method for forming the semiconductor device further includes: sequentially forming a high dielectric constant (high-k) layer, a capping layer and a gate electrode on each of the first gate dielectric layer, the second gate dielectric layer and the third gate dielectric layer to form a first gate structure in the first active region structure, a second gate structure in the second active region, and a third gate structure in the third active region.

In some embodiments, the method for forming a semiconductor device further includes: forming a first source/drain in the first active region of the substrate at opposite sides of the first gate structure; forming a second source/drain in the second active region of the substrate at opposite side of the second gate structure; and forming a third source/drain in the third active region of the substrate at opposite sides of the third gate structure.

In some embodiments, bottom surfaces of the isolation structures include first portions at the same level as a bottom surface of the element isolation structure and second portions being oblique with respective to the first portions.

In some embodiments, depths of the second portions are greater than depths of the first portions.

In some embodiments, slopes of the second portions are greater than slopes of the first portions.

In some embodiments, a process of forming the first gate dielectric material layer includes a local oxidation of silicon (LOCOS) process, and a process of forming the isolation structures and the element isolation structure includes a shallow trench isolation (STI) process.

An embodiment of the present invention provides a semiconductor device including a substrate and a first element, a second element and a third element. The substrate includes the element isolation structure defining the first active region, the second active region and the third active region. The first element, the second element and the third element are respectively disposed in the first active region, the second active region and the third active region. The first element includes the first gate dielectric embedded in the first active region of the substrate and the isolation structures embedded in the substrate at opposite sides of the first gate dielectric layer. The bottom surfaces of the isolation structures include first portions at the same level as a bottom surface of the element isolation structure and second portions being oblique with respective to the first portions.

In some embodiments, depths of the second portions are greater than depths of the first portions.

In some embodiments, slopes of the second portions are greater than slopes of the first portions.

In some embodiments, a horizontal area of the first element is larger than a horizontal area of the second element and a horizontal area of the third element.

In some embodiments, a top surface of the first gate dielectric layer is coplanar with top surfaces of the isolation structures.

In some embodiments, the second element includes a second gate dielectric layer disposed on the second active region of the substrate, and the third element includes a third gate dielectric layer disposed on the third active region of the substrate.

Based on the above, in the aforementioned semiconductor device and the method for forming the same, the first trenches and the second trench where the isolation structures and the element isolation structure are respectively formed therein are formed after the first gate dielectric material layer is formed in the substrate, so that the bottom surfaces of the isolation structures include the first portions at the same level as the bottom surface of the element isolation structure and the second portions being oblique with respective to the first portions As such, the thinning phenomenon does not occur at the edges of the gate dielectric layer adjacent to the isolation structures, and therefore the reliability and performance of the semiconductor device are good since the breakdown voltage of the semiconductor device is not affected by the above thinning phenomenon.

In addition, since there is no need to form a recess in a region of the substrate defined by the isolation structures and where the gate dielectric layer is to be formed, the active region of the semiconductor device will not be affected by the etching process used to form the recess. As such, the reliability of the semiconductor device can be improved and the problem related to the etching loading effect can be avoided as well, which allows the semiconductor device to have good yield and good performance.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 to FIG. 12 are schematic cross-section views illustrating a method for forming a semiconductor device in an embodiment of the invention.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The invention will be described more comprehensively below with reference to the drawings for the embodiments. However, the invention may also be implemented in different forms rather than being limited by the embodiments described in the invention. Thicknesses of layer and region in the drawings are enlarged for clarity. The same reference numbers are used in the drawings and the description to indicate the same or like parts, which are not repeated in the following embodiments.

It will be understood that when an element is referred to as being “on” or “connected” to another element, it may be directly on or connected to the other element or intervening elements may be present. If an element is referred to as being “directly on” or “directly connected” to another element, there are no intervening elements present. As used herein, “connection” may refer to both physical and/or electrical connections, and “electrical connection” or “coupling” may refer to the presence of other elements between two elements. As used herein, “electrical connection” may refer to the concept including a physical connection (e.g., wired connection) and a physical disconnection (e.g., wireless connection).

As used herein, “about”, “approximately” or “substantially” includes the values as mentioned and the average values within the range of acceptable deviations that can be determined by those of ordinary skill in the art. Consider to the specific amount of errors related to the measurements (i.e., the limitations of the measurement system), the meaning of “about” may be, for example, referred to a value within one or more standard deviations of the value, or within ±30%, ±20%, ±10%, ±5%. Furthermore, the “about”, “approximate” or “substantially” used herein may be based on the optical property, etching property or other properties to select a more acceptable deviation range or standard deviation, but may not apply one standard deviation to all properties.

The terms used herein are used to merely describe exemplary embodiments and are not used to limit the present disclosure. In this case, unless indicated in the context specifically, otherwise the singular forms include the plural forms.

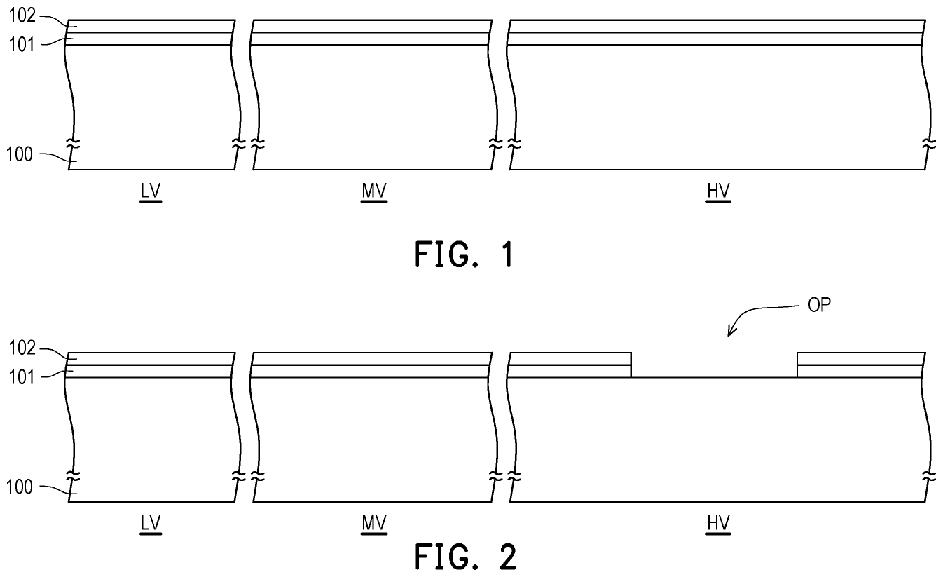

FIG. 1 to FIG. 10 are schematic cross-section views illustrating a method for forming a semiconductor device in an embodiment of the invention.

In some embodiments, a method of forming a semiconductor device (e.g., a semiconductor device 10 shown in FIG. 12) may include the following steps.

Firstly, referring to FIG. 1, a substrate 100 including a first active region HV, a second active region MV and a third active region LV is provided. In some embodiments, the first active region HV may be a region where a high-voltage semiconductor element is disposed; the second active region MV may be a region where a middle-voltage semiconductor element is disposed; and the third active region LV may be a region where a low-voltage semiconductor element is disposed. In some embodiments, the operating voltage (e.g., 20V or 28V) of the high-voltage semiconductor element disposed in the first active region HV may be higher than the operating voltage (e.g., 8V) of the middle-voltage semiconductor element disposed in the second active region MV. In some embodiments, the operating voltage of the middle-voltage semiconductor element disposed in the second active region MV may be higher than the operating voltage (e.g., 0.9V) of the low-voltage semiconductor element disposed in the third active region LV.

The substrate 100 may include a semiconductor substrate or a semiconductor-on-insulator (SOI) substrate. The semiconductor materials in the semiconductor substrate or in the SOI substrate may include an element semiconductor, an alloy semiconductor, or a compound semiconductor. For example, the element semiconductor may include Si or Ge. The alloy semiconductor may include SiGe, SiGeC, or the like. The compound semiconductor may include SiC, III-V semiconductor materials, or II-VI semiconductor materials. The III-V semiconductor materials may include GaN, GaP, GaAs, AlN, AlP, AlAs, InN, InP, InAs, GaNP, GaNAs, GaPAs, AlNP, AlNAs, AlPAs, InNP, InNAs, InPAs, GaAlNP, GaAlNAs, GaAlPAs, GaInNP, GaInNAs, GalnPAs, InAlNP, InAlNAs, or InAlPAs. The II-VI semiconductor materials may include CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, or HgZnSTe. The semiconductor material may be doped with a dopant of a first conductivity type or a dopant of a second conductivity type complementary to the first conductivity type. For example, the first conductivity type may be n- type, whereas the second conductivity type may be p-type.

Next, a first gate dielectric material layer (e.g., a first gate dielectric material layer 112 shown in FIG. 4) embedded in the first active region HV of the substrate 100 is formed. In some embodiments, the first gate dielectric material layer may be formed by the following steps.

Firstly, continuously referring to FIG. 1, a first material layer 101 and a second material layer 102 are formed on the substrate 100 in sequence. The material of the first material layer 101 may be different from the material of the second material layer 102. In some embodiments, the first material layer 101 may include an oxide such as silicon oxide. The second material layer 102 may include a nitride such as silicon nitride.

Next, referring to FIG. 2, an opening OP exposing a portion of the substrate 100 is formed in the first material layer 101 and the second material layer 102 of the first active region HV.

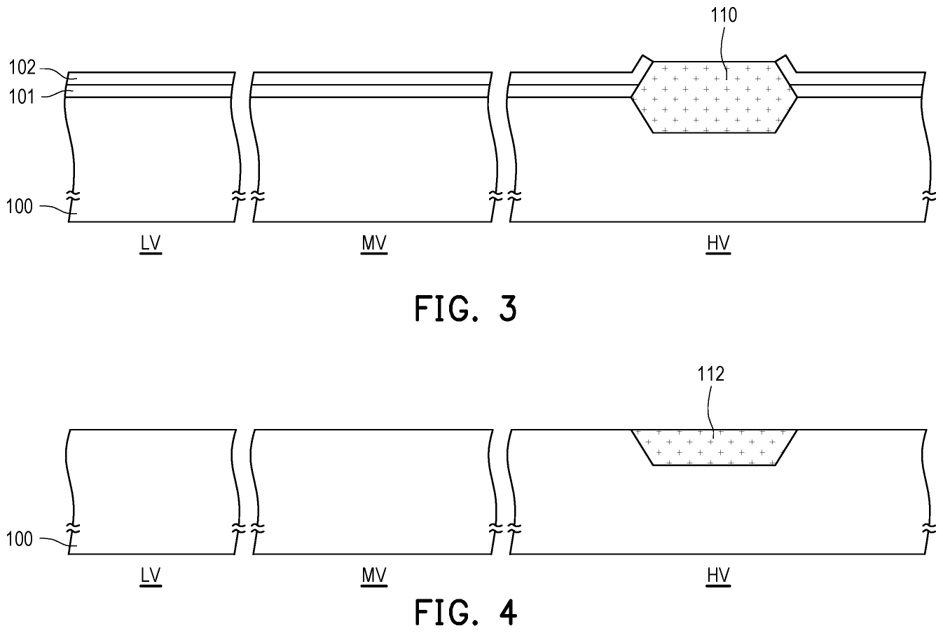

Then, referring to FIG. 3, a local oxidation of silicon (LOCOS) process may be performed on the substrate 100 to form a LOCOS layer 110 in the first active region HV of the substrate 100. In some embodiments, the LOCOS process may include a thermal oxidation process. The LOCOS layer 110 may include an oxide such as silicon oxide.

After that, referring to FIG. 3 and FIG. 4, a planarization process (e.g., an etch-back process) is performed on the LOCOS layer 110 and the first material layer 101 and the second material layer 102 are removed accordingly, so as to form a first gate dielectric material layer 112 embedded in the first active region HV of the substrate 100.

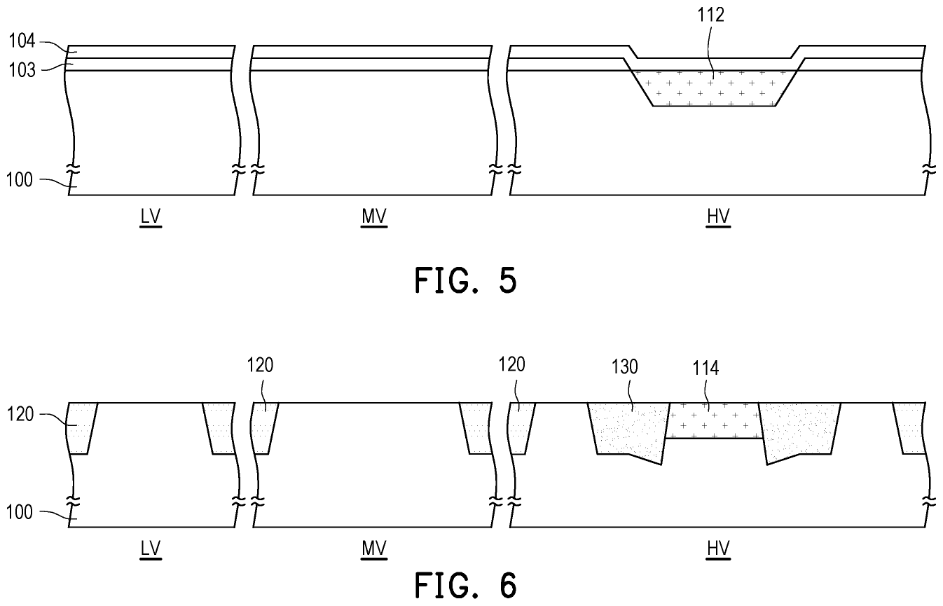

Next, referring to FIG. 5, a third material layer 103 and a fourth material layer 104 are sequentially deposited on the substrate 100 again. The material of the third material layer 103 may be different from the material of the fourth material layer 104. In some embodiments, the third material layer 103 may include an oxide such as silicon oxide. The fourth material layer 104 may include a nitride such as silicon nitride. In some embodiments, the third material layer 103 may be formed through a thermal oxidation process, so that the third material layer 103 is formed only on the substrate 100 and not on the first gate dielectric material layer 112. In some embodiments, the fourth material layer 104 may be formed on the third material layer 103 and the first gate dielectric material layer 112 by a process such as a chemical vapor deposition (CVD).

Then, referring to FIG. 6, an element isolation structure 120 defining the first active region HV, the second active region MV and the third active region LV is formed in the substrate 100, and isolation structures 130 are formed in the first active region HV of the substrate 100. In some embodiments, the element isolation structure 120 and the isolation structures 130 may be simultaneously formed through the same process. In some embodiments, the element isolation structure 120 and the isolation structures 130 may be formed by the following steps. Firstly, referring to FIG. 5 and FIG. 6, portions of the first gate dielectric material layer 112 and portions of the substrate 100 next to the portions of the first gate dielectric material layer 112 are removed to form a first gate dielectric layer 114 of a first element and first trenches (i.e., trenches where the isolation structures 130 are formed therein) at opposite sides of the first gate dielectric layer 114. Referring to FIG. 5 and FIG. 6, a second trench (i.e., a trench where the element isolation structure 120 is formed therein) defining the first active region HV, the second active region MV, and the third active region LV may be formed in the substrate 100 by removing a portion of the substrate 100. Next, an insulating material is filled into the first trenches and the second trench to form the isolation structures 130 in the first trenches and the element isolation structure 120 in the second trench. The third material layer 103 and the fourth material layer 104 are removed after the element isolation structure 120 and the isolation structures 130 are formed. In some embodiments, the insulating material may include insulating materials such as oxides (e.g., silicon oxides). In some embodiments, the top surface of the first gate dielectric layer 114 is coplanar with the top surface of isolation structure 130. In some embodiments, the first trenches and the second trench may be simultaneously formed in the same process.

In some embodiments, in the case where the portions of the first gate dielectric material layer 112 and the portions of the substrate 100 next to the portions of the first gate dielectric material layer 112 are removed under the same etching process, bottom surfaces of the isolation structures 130 are formed to include first portions at the same level as a bottom surface of the element isolation structure 120 and second portions being oblique with respective to the first portions since different materials will have different etching rates under the same etching process. For example, in the cases where the etching rate of the first gate dielectric material layer 112 is greater than the etching rate of the substrate 100, the slopes of the second portions may be greater than the slopes of the first portions, and the depths of the second portions may be greater than the depths of the first portions.

In the cases where the first gate dielectric layer 114 is formed through the above processes, the thinning phenomenon does not occur at the edges of the first gate dielectric layer 114 adjacent to the isolation structures 130, so that the reliability and performance of the semiconductor device are good since the breakdown voltage of the semiconductor device is not affected by the thinning phenomenon.

In some embodiments, the process of forming the first gate dielectric material layer 112 may include a local oxidation of silicon (LOCOS) process, and the process of forming the element isolation structure 120 and isolation structures 130 may include a shallow trench isolation (STI) process.

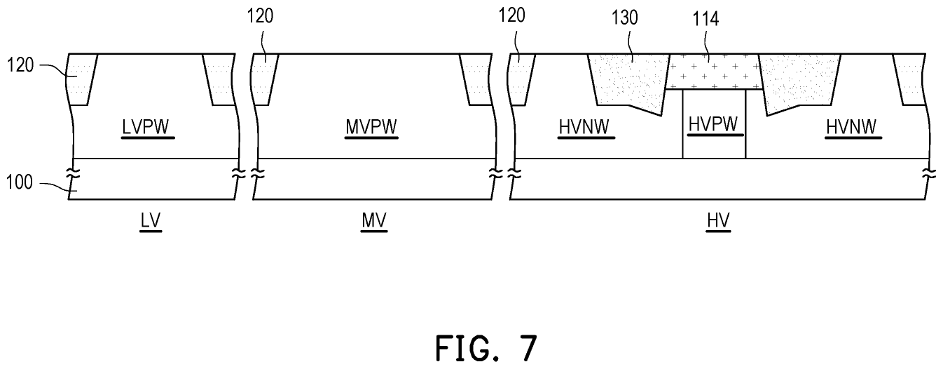

After that, referring to FIG. 7, a first well region HVNW is formed in the first active region HV of the substrate 100; a second well region MVPW is formed in the second active region MV of substrate 100; and a third well region LVPW is formed in the third active region LV of the substrate 100. In some embodiments, the first well region HVNW may have a different conductivity type than the second well region MVPW and third well region LVPW. For example, the first well region HVNW may be doped with a dopant with the first conductivity type (e.g., a n-type dopant), whereas the second well region MVPW and third well region LVPW may be doped with a dopant with the second conductivity type (e.g., a p-type dopant).

Then, a first doped region HVPW is formed in a region of the first active region HV defined by the isolation structures 130. In some embodiments, the first doped region HVPW may have a conductivity type different from the first well region HVNW. As such, the first doped region HVPW may divide the first well region HVNW into two parts. For example, the first well region HVNW may be doped with a dopant with the first conductivity type (e.g., a n-type dopant), whereas the first doped region HVPW may be doped with a dopant with the second conductivity type (e.g., a p-type dopant).

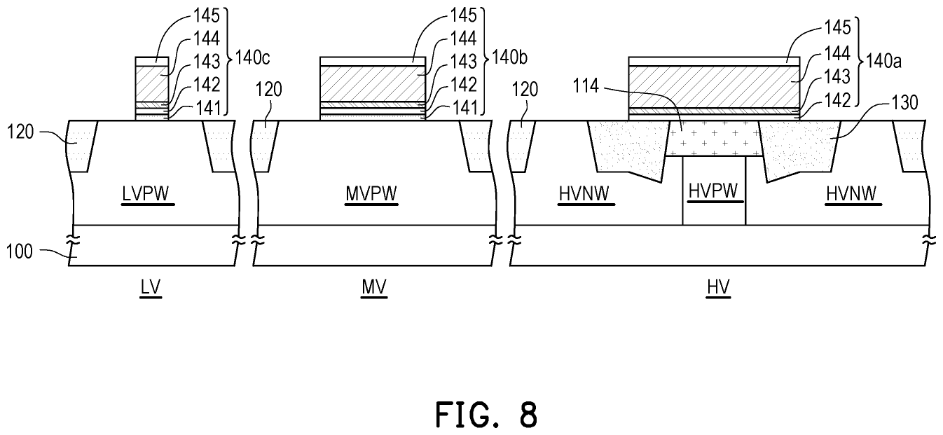

Next, referring to FIG. 8, after the element isolation structure 120 and the isolation structures 130 are formed, a second gate dielectric layer 141 of a second element and a third gate dielectric layer 141 of a third element are respectively formed on the second active region MV and the third active region LV of the substrate 100. In some embodiments, the second gate dielectric layer 141 and the third gate dielectric layer 141 include materials such as silicon oxides used for the gate dielectric layer.

Then, a high dielectric constant (high-k) layer 142, a capping layer 143, a sacrificial gate layer 144 and a hard mask layer 145 are sequentially formed on each of the first gate dielectric layer 114, the second gate dielectric layer 141 and the third gate dielectric layer 141 to form a first stacked structure 140 in the first active region HV, a second stacked structure 140b in the second active region MV and the third stacked structure 140c in the third active region LV.

In some embodiments, the high-k layer 142 may include dielectric materials having high dielectric constants. For example, the dielectric materials having high dielectric constants may be materials having dielectric constants higher than that of silicon oxide (about 3.9). In some embodiments, the high-k layer 142 may include HfO₂, TiO₂, HfZrO, Ta₂O₃, HfSiO₄, ZrO₂, ZrSiO₂, LaO, AlO, ZrO, TiO, Ta₂O₅, Y₂O₃, BaZrO, HfZrO, HfLaO, HfSiO, LaSiO, AlSiO, HfTaO, HfTiO, Al₂O₃, Si₃N₄, SiON or combinations thereof. In some embodiments, the capping layer 143 may include TiN. In some embodiments, the sacrificial gate layer 144 may include polysilicon. In some embodiments, the hard mask layer 145 may include oxides, nitrides, or combinations thereof.

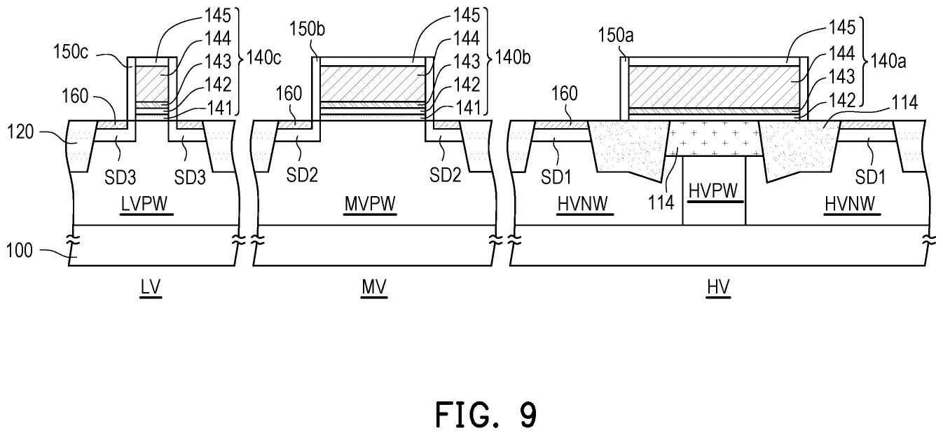

After that, referring to FIG. 9, first spacers 150a, second spacers 150b and third spacers 150c are respectively formed on the opposite sidewalls of the first stacked structure 140a, the second stacked structure 140b and the third stacked structure 140c. The first spacers 150a, the second spacers 150b, and the third spacers 150c may each include silicon oxides, silicon nitrides, or combinations thereof.

Then, first source/drains SD1 are formed in regions defined by the element isolation structure 120 and isolation structures 130 in the first well region HVNW; second source/drains SD2 are formed in the second well region MVPW at the opposite sides of the second stacked structure 140b; third source/drains SD3 are formed in the third well region LVPW at the opposite sides of the third stacked structure 140c.

Next, silicide layers 160 are respectively formed in the first source/drains SD1, the second source/drains SD2 and third source/drains SD3. In some embodiments, the silicide layers 160 may be formed by performing a silicidation process on the first source/drains SD1, the second source/drains SD2, and the third source/drains SD3. The silicide layers 160 may include tungsten silicide, titanium silicide, cobalt silicide, zirconium silicide, platinum silicide, molybdenum silicide, copper silicide or nickel silicide, or combinations thereof.

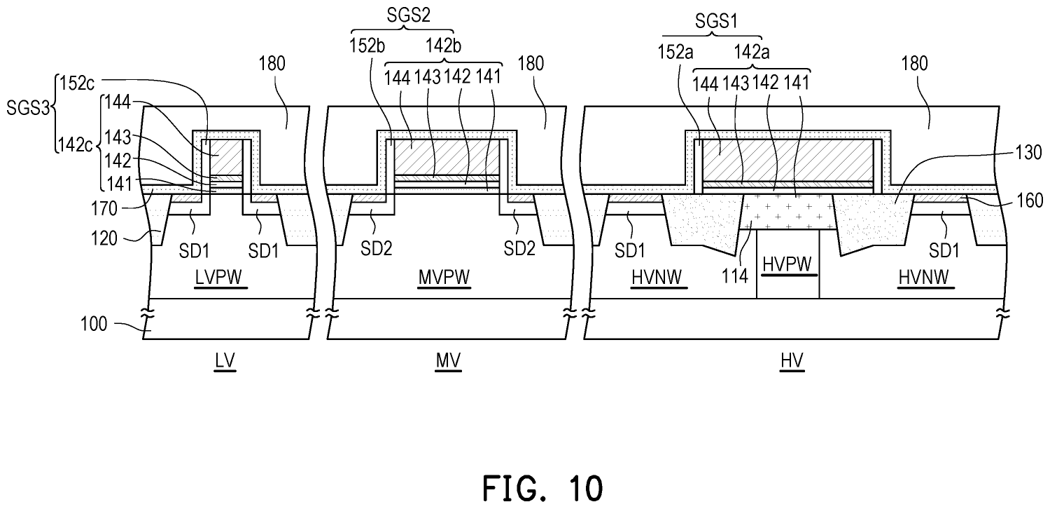

After that, referring to FIG. 9 and FIG. 10, the hard mask layers 145 in the first stacked structure 140a, the second stacked structure 140b and the third stacked structure 140c are removed to form a first sacrificial gate structure SGS1, a second sacrificial gate structure SGS2 and a third sacrificial gate structure SGS3. In some embodiments, in the step of removing the hard mask layers 145, portions of the first spacer 150a, the second spacers 150b and the third spacers 150c located on the side surfaces of the hard mask layers 145 are removed as well, so that the first sacrificial gate structure SGS1 is formed to include a first stacked structure 142a and spacers 152a, the second sacrificial gate structure SGS2 is formed to include a second stacked structure 142b and spacers 152b, and the third sacrificial gate structure SGS3 is formed to include a third stacked structure 142c and spacers 152c.

Then, referring to FIG. 10, an etching stop material layer 170 and a dielectric material layer 180 are formed on the substrate 100 in sequence. The etching stop material layer 170 may be conformally formed on the surface of the substrate 100 and the surfaces of the first sacrificial gate structure SGS1, the second sacrificial gate structure SGS2, and the third sacrificial gate structure SGS3. The dielectric material layer 180 may cover the first sacrificial gate structure SGS1, the second sacrificial gate structure SGS2 and the third sacrificial gate structure SGS3. The etching stop material layer 170 may include materials such as silicon nitrides. The dielectric material layer 180 may include a dielectric material such as a silicon oxide.

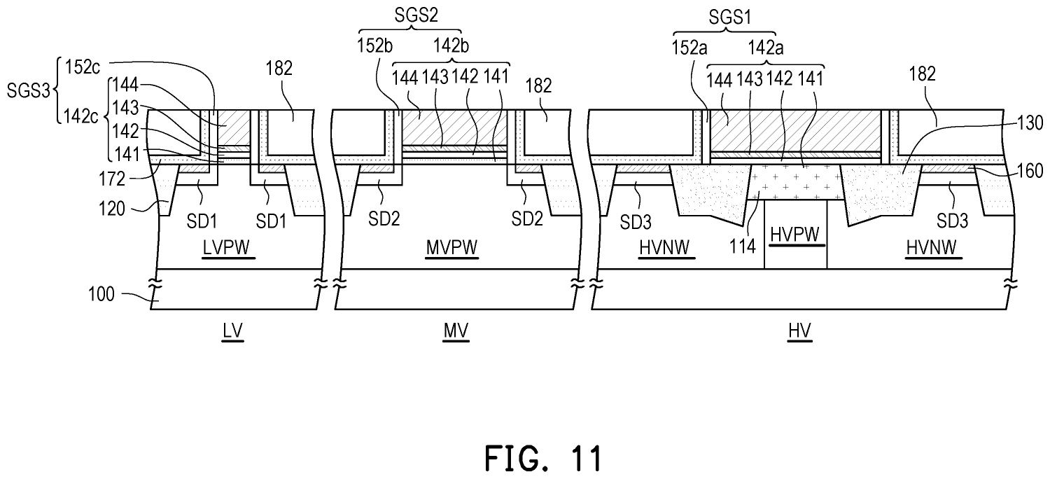

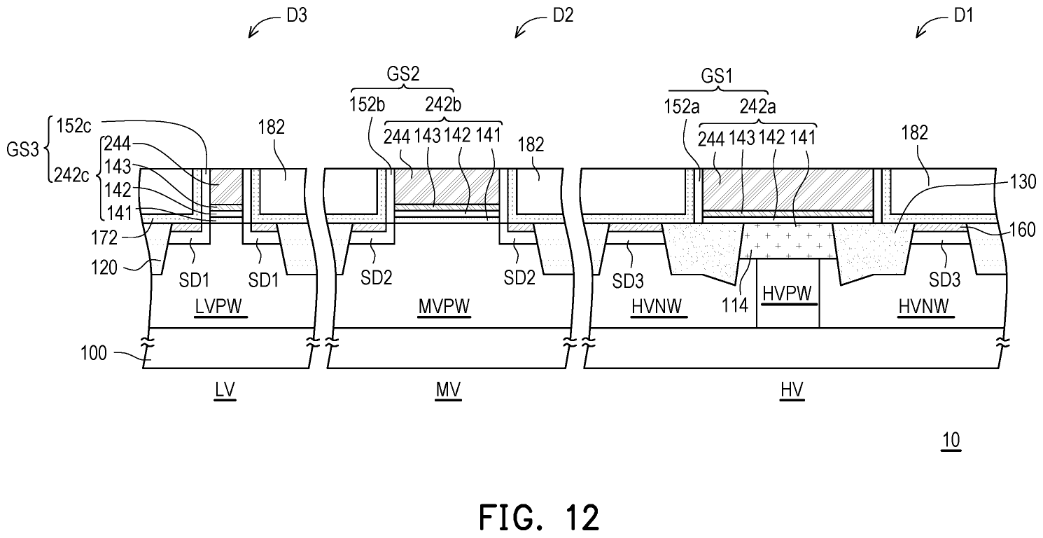

Next, referring to FIG. 10 and FIG. 11, a planarization process (e.g., a CMP process) is performed on the dielectric material layer 180 and the etching stop material layer 170 to form an etching stop layer 172 and a dielectric layer 182.

After that, referring to FIG. 11 and FIG. 12, the sacrificial gate layers 144 in the first stacked structure 142a, the second stacked structure 142b and the third stacked structure 142c are removed and then metal materials are filled into the spaces formed by removing the sacrificial gate layers 144, so that a first stacked structure 242a, a second stacked structure 242b and a third stacked structure 242c including metal gates 244 are formed after a planarization process (e.g., a CMP process) is performed on the metal materials to remove excess metal materials on the dielectric layer 182. From above, a first gate structure GS1, a second gate structure GS2 and a third gate structure GS3 are respectively formed on the first active region HV, the second active region MV and the third active region LV. The metal materials may include tantalum nitride (TaN), nickel silicon (NiSi), cobalt silicon (CoSi), molybdenum (Mo), copper (Cu), tungsten (W), aluminum (Al), cobalt (Co), zirconium (Zr), platinum (Pt) or other suitable materials. The first gate structure GS1 may include the first stacked structure 242a and the spacers 152a. The second gate structure GS2 may include the second stacked structure 242b and the spacers 152b. The third gate structure GS3 may include the third stacked structure 242c and the spacers 152c.

Based on the above, in the aforementioned method for forming the semiconductor device 10, since there is no need to form a recess in a region of the substrate 100 defined by the isolation structures 130 and where the gate dielectric layer 114 is to be formed, the first active region HV will not be affected by the etching process used to form the recess. As such, the reliability of the semiconductor device 10 can be improved and the problem related to the etching loading effect can be avoided as well, which allows the semiconductor device 10 to have good yield and good performance.

On the other hands, the first trenches and the second trench where the isolation structures 130 and the element isolation structure 120 are respectively formed therein are formed after the first gate dielectric material layer 112 is formed in the substrate 100, so that the bottom surfaces of the isolation structures 130 are formed to include the first portions at the same level as the bottom surface of the element isolation structure 120 and the second portions being oblique with respective to the first portions As such, the thinning phenomenon does not occur at the edges of the gate dielectric layer 114 adjacent to the isolation structures 130, and therefore the reliability and performance of the semiconductor device 10 are good since the breakdown voltage of the semiconductor device 10 is not affected by the thinning phenomenon.

Hereinafter, the semiconductor structure 10 will be illustrated with reference to FIG. 12, but the method for forming the semiconductor structure 10 of the present invention is not limited thereto.

The semiconductor device 10 may include a substrate 100 and a first element D1, a second element D2 and a third element D3. The substrate 100 includes an element isolation structure 120 defining a first active region HV, a second active region MV, and a third active region LV. The first element D1, the second element D2 and the third element D3 are respectively disposed in the first active region HV, the second active region MV and the third active region LV. The first element D1 includes a first gate dielectric layer 114 embedded in the first active region HV of the substrate 100 and isolation structures 130 embedded in the substrate 100 at the opposite sides of the first gate dielectric layer 114. The bottom surfaces of the isolation structures 130 include first portions at the same level as the bottom surface of the element isolation structure 120 and second portions being oblique with respective to the first portions. In some embodiments, the depths of the second portions of the isolation structures 130 are greater than the depths of the first portions of the isolation structures 130. In some embodiments, the slopes of the second portions of the isolation structures 130 are greater than the slopes of the first portions of the isolation structures 130. In some embodiments, the top surface of first gate dielectric layer 114 is coplanar with the top surfaces of the isolation structures 130.

In some embodiments, the horizontal area of the first element D1 is greater than the horizontal area of the second element D2 and the horizontal area of the third element D3. In some embodiments, the second element D2 includes a second gate dielectric layer 141 disposed on the second active region MV of the substrate 100, and the third element D3 includes a third gate dielectric layer 141 disposed on the third active region LV of the substrate 100.

In summary, in the aforementioned semiconductor device and the method for forming the semiconductor device, the first trenches and the second trench where the isolation structures and the element isolation structure are respectively formed therein are formed after the first gate dielectric material layer is formed in the substrate, so that the bottom surfaces of the isolation structures are formed to include the first portions at the same level as the bottom surface of the element isolation structure and the second portions being oblique with respective to the first portions As such, the thinning phenomenon does not occur at the edges of the gate dielectric layer adjacent to the isolation structures, and therefore the reliability and performance of the semiconductor device are good since the breakdown voltage of the semiconductor device is not affected by the above thinning phenomenon.

In addition, since there is no need to form a recess in a region of the substrate defined by the isolation structures and where the gate dielectric layer is to be formed, the active region of the semiconductor device will not be affected by the etching process used to form the recess. As such, the reliability of the semiconductor device can be improved and the problem related to the etching loading effect can be avoided as well, which allows the semiconductor device to have good yield and good performance.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A method for forming a semiconductor device, comprising:
providing a substrate comprising a first active region, a second active region and a third active region;
forming a first gate dielectric material layer embedded in the first active region of the substrate;
removing portions of the first gate dielectric material layer and portions of the substrate next to the portions of the first gate dielectric material layer to form a first gate dielectric layer of a first element and first trenches at opposite sides of the first gate dielectric layer;
forming a second trench defining the first active region, the second active region and the third active region in the substrate; and
filling the first trenches and the second trench with an insulating material to form isolation structures in the first trenches and to form an element isolation structure in the second trench.

2. The method of claim 1, further comprising:
forming a second gate dielectric layer of a second element and a third gate dielectric layer of a third element respectively on the second active region and the third active region of the substrate after forming the isolation structures and the element isolation structure.

3. The method of claim 2, wherein a horizontal area of the first element is greater than a horizontal area of the second element and a horizontal area of the third element.

4. The method of claim 3, wherein a top surface of the first gate dielectric layer is coplanar with top surfaces of the isolation structures.

5. The method of claim 2, further comprising:
sequentially forming a high dielectric constant (high-k) layer, a capping layer and a gate electrode on each of the first gate dielectric layer, the second gate dielectric layer and the third gate dielectric layer to form a first gate structure in the first active region structure, a second gate structure in the second active region, and a third gate structure in the third active region.

6. The method of claim 5 further comprising:
forming a first source/drain in the first active region of the substrate at opposite sides of the first gate structure;
forming a second source/drain in the second active region of the substrate at opposite side of the second gate structure; and
forming a third source/drain in the third active region of the substrate at opposite sides of the third gate structure.

7. The method of claim 1, wherein bottom surfaces of the isolation structures comprise first portions at the same level as a bottom surface of the element isolation structure and second portions being oblique with respective to the first portions.

8. The method of claim 7, wherein depths of the second portions are greater than depths of the first portions.

9. The method of claim 7, wherein slopes of the second portions are greater than slopes of the first portions.

10. The method of claim 7, wherein a process of forming the first gate dielectric material layer comprises a local oxidation of silicon (LOCOS) process, and a process of forming the isolation structures and the element isolation structure comprises a shallow trench isolation (STI) process.

11. A semiconductor device, comprising:
a substrate comprising an element isolation structure defining a first active region, a second active region and a third active region; and
a first element, a second element and a third element respectively disposed in the first active region, the second active region and the third active region,
wherein the first element comprises:
a first gate dielectric layer buried in the first active region of the substrate; and
isolation structures embedded in the substrate at opposite sides of the first gate dielectric layer, wherein bottom surfaces of the isolation structures comprise first portions at the same level as a bottom surface of the element isolation structure and second portions being oblique with respective to the first portions.

12. The semiconductor device of claim 11, wherein depths of the second portions are greater than depths of the first portions.

13. The semiconductor device of claim 11, wherein slopes of the second portions are greater than slopes of the first portions.

14. The semiconductor device of claim 11, wherein a horizontal area of the first element is larger than a horizontal area of the second element and a horizontal area of the third element.

15. The semiconductor device of claim 14, wherein a top surface of the first gate dielectric layer is coplanar with top surfaces of the isolation structures.

16. The semiconductor device of claim 11, wherein the second element comprises a second gate dielectric layer disposed on the second active region of the substrate, and the third element comprises a third gate dielectric layer disposed on the third active region of the substrate.
